(19) United States
(12) Patent Application Publication
(10) Pub. No.: US 2012/0240977 A1
(43) Pub. Date: Sep. 27, 2012

(54) UTILIZING ENERGETIC RADIATION IN AN ENCLOSED SPACE

(75) Inventor: Mordechai Nisenson, Haifa (IL)

(73) Assignee: INTERNATIONAL BUSINESS MACHINES CORPORATION, Armonk, NY (US)

(21) Appl. No.: 13/489,472

(22) Filed: Jun. 6, 2012

Related U.S. Application Data
(62) Division of application No. 12/197,327, filed on Aug. 25, 2008.

(51) Int. Cl. H01L 31/052; H01L 31/042

(52) U.S. Cl. 136/246; 136/244

(57) ABSTRACT

Systems of utilizing energetic radiation in an enclosed space is disclosed. For example, an embodiment of a system of utilizing energetic radiation in an enclosed space includes: one or more photovoltaic cells, positioned at one or more predetermined positions in the enclosed space, adapted to convert radiation in the enclosed space into electric power; and an electric circuit to utilize the electric power to perform a function associated with the enclosed space. Other embodiments are described and claimed.

### CROSS-REFERENCE TO RELATED APPLICATIONS

The present application is a divisional application of U.S. patent application Ser. No. 12/197,327 which was filed on Aug. 25, 2008.

### FIELD

Some embodiments relate to using photovoltaic cells for converting energetic radiation into electric power.

### BACKGROUND

An enclosed space such as a machine room, a computer room, an office, a storage room, the space inside a house, or the like, may contain various machines, for example, electrical appliances and/or electronic devices, such as computers and related equipment, which may operate continually for long periods of time, thereby generating significant amounts of heat and radiation in the enclosed space.

Similarly, an enclosed space inside a machine or an electrical/electronic device may contain internal components, e.g., electrical circuits, electronic circuits and/or mechanical components, which may operate continually for long periods of time, thereby generating significant amounts of heat and radiation inside the machine or device.

Heat is generated during operation of machines, devices, and their internal components, for example, due to friction of mechanical elements, resistance of electric wiring and/or other components, heating up of silicon chips, e.g., in the case of computers equipment, etc. In many instances, for example, more than half of the amount of energy consumed for operation of a machine, an electric device, or one or more components thereof is transformed into undesired heat and radiation, which reduces the efficiency of the machine or device.

A significant portion of the heat generated by machines/devices and their internal components is in the form of electromagnetic radiation, particularly radiation in the infrared range, which spreads in the enclosed space. Most of the infrared radiation in the enclosed space is transformed into heat, which is produced as the infrared radiation is absorbed by materials on the radiation path, thereby contributing significantly to heating the machines/devices and their surroundings.

In addition to the heat and associated radiation, some machines, devices and components in enclosed spaces generate electromagnetic radiation in various spectral ranges; for example, Gamma ray radiation in nuclear plants, X-ray radiation from imaging systems (e.g., in hospitals), ultraviolet (UV) radiation (e.g., in tanning salons), visible light, etc. These types of radiation spread in the enclosed and absorbed by designated and/or undesignated substrates on the radiation path, often with adverse effects. In order to operate properly, many machines require a heat dissipation component, or a cooling component, to cool the machine and its surroundings and maintain the machine at a desired operating temperature. Such components may include a ventilation and/or exhaust fan, an air conditioner, a water-cooling system, or the like.

Unfortunately, the heat dissipation component may consume a considerable amount of energy in addition to the energy consumed by the machine. In addition, the heat dissipation component itself may generate heat in the enclosed space, making heat dissipation increasingly difficult and energy consuming.

### SUMMARY

Some embodiments include a system of utilization energetic radiation in an enclosed space, the system including: one or more photovoltaic cells, positioned at one or more predetermined positions in the enclosed space, adapted to convert radiation in the enclosed space into electric power; and an electric circuit to utilize the electric power to perform a function associated with the enclosed space.

In some embodiments, the electric circuit includes an electric component that is physically associated with the enclosed space that performs the function, and that is physically associated with the enclosed space.

In some embodiments, the electric component includes a heat dissipation device to cool at least a portion of the enclosed space.

In some embodiments, the heat dissipation device includes a fan to circulate air in the enclosed space.

In some embodiments, the electric circuit includes a battery configured to be charged by at least part of the electric power.

In some embodiments, the enclosed space includes a space enclosed within a housing of a machine.

In some embodiments, the machine includes an electronic device.

In some embodiments, the electric power is coupled to a power supply of the electronic device.

In some embodiments, the electronic device comprises a computing device.

In some embodiments, the enclosed space contains one or more machines that emit at least part of the energetic radiation.

In some embodiments, the enclosed space comprises a room and at least one of the machines comprises a computer.

Some embodiments may provide other and/or additional benefits and/or advantages.

### BRIEF DESCRIPTION OF THE DRAWINGS

For simplicity and clarity of illustration, elements shown in the figures have not necessarily been drawn to scale. For example, the dimensions of some of the elements may be exaggerated relative to other elements for clarity of presentation. Furthermore, reference numerals may be repeated among the figures to indicate corresponding or analogous elements. The figures are listed below.

FIG. 1 is a schematic illustration of a system utilizing radiation emitted in an enclosed space, in accordance with some demonstrative embodiments; and

FIG. 2 is a schematic block diagram illustration of a system utilizing radiation emitted in an enclosed space, in accordance with some demonstrative embodiments.

### DETAILED DESCRIPTION

In the following detailed description, numerous specific details are set forth in order to provide a thorough understanding of some embodiments. However, it will be understood by persons of ordinary skill in the art that some embodiments may be practiced without these specific details. In other instances, well-known methods, procedures, components, units and/or circuits have not been described in detail so as not to obscure the discussion.

The terms “plurality” and “a plurality” as used herein includes, for example, “multiple” or “two or more”. For example, “a plurality of items” includes two or more items.

The term “machine” as used herein includes any type of device or component that generates heat and/or electromagnetic radiation during operation; for example, electrical or electronic devices, e.g. computers and related equipment, appliances, hi-fi systems, televisions, and/or any other type of energy-consuming machine.

The term “enclosed space” as used herein includes, for example, an indoor space, a room, a computer room, a machine room, a hall, an office, a computer data center; the space inside an apartment, a house, a warehouse, a building; a space enclosed or partially enclosed within walls, a ceiling and a floor.

In addition, the term “enclosed space” as used herein includes, for example, an interior space of a machine or a volume enclosed within a housing of a machine, for example, of an electrical device, e.g., a computer, or the like.

As an overview, some embodiments may provide devices, systems and/or methods of utilizing electromagnetic radiation in an enclosed space, e.g., infrared radiation or other electromagnetic spectra, to power a component associated with the enclosed space.

A machine and/or one or more components thereof operating on electricity or on other fuels may generate heat and/or electromagnetic radiation, e.g., infrared radiation associated with heat emission, or other spectra of electromagnetic radiation, which may spread within the surroundings of the machine and/or of the components thereof, for example, within a housing of the machine, and/or throughout an enclosed space that contains one or more machines, such as a machine room, e.g., a computer room.

Some embodiments, for example, may include one or more photovoltaic cells positioned in the enclosed space to convert radiation emitted within the enclosed space into electric voltage. The electric voltage may be used to power or to contribute to a power supply of one or more electrical components in the enclosed space, or to perform other operations associated with the enclosed space. For example, according to some embodiments, one or more electrical components powered by the photovoltaic cells may operate to dissipate heat from the enclosed space, e.g., in order to maintain various machines and/or components in the enclosed space at a desired operational temperature, as described below.

In some embodiments, for example, the enclosed space includes a room, an office, a computing data center, or the like. In these embodiments, one or more photovoltaic cells may be positioned along one or more interior surfaces of the enclosed space, for example, along the ceiling, walls and/or floor of the enclosed space, or at other suitable positions in the enclosed space, to convert radiation spread throughout the enclosed space into electric power. The one or more photovoltaic cells may be connected to one or more electrical devices associated with the enclosed space, and may supply electric voltage to power the one or more electrical devices. The electrical devices may include, for example, a ventilation fan or exhaust fan, to circulate air in the enclosed space and thus cool at least part of the enclosed space, e.g., if the enclosed space contains one or more machines susceptible to heat.

In other embodiments the enclosed space includes an interior space within a housing of a machine. In these embodiments, photovoltaic cells may be positioned along interior surfaces of the housing of the machine, e.g., along the inner walls of a housing of a computing device. The one or more photovoltaic cells may be internally connected to other elements of the machine, and may supply electric power to one or more electrical components in the machine. The electrical components may include, for example, a fan to circulate air within the housing and thus to cool elements of the machine, or any other electrical component useful for the operation of the machine.

Some embodiments may include an electric circuit to connect the photovoltaic cells to the components empowered thereby. The electric circuit may include, for example, a Direct Current to Alternate Current (DC to AC) inverter, a voltage/current regulator to regulate the electrical voltage/current provided to the electrical components, and/or one or more batteries to retain the electric energy to be provided to the electrical components.

A system according to some embodiments may conserve or “recycle” energy, i.e., by converting energetic radiation emitted in the enclosed space into electrical energy that powers or contributes to the operation of one or more electrical components or devices associated with the enclosed space.

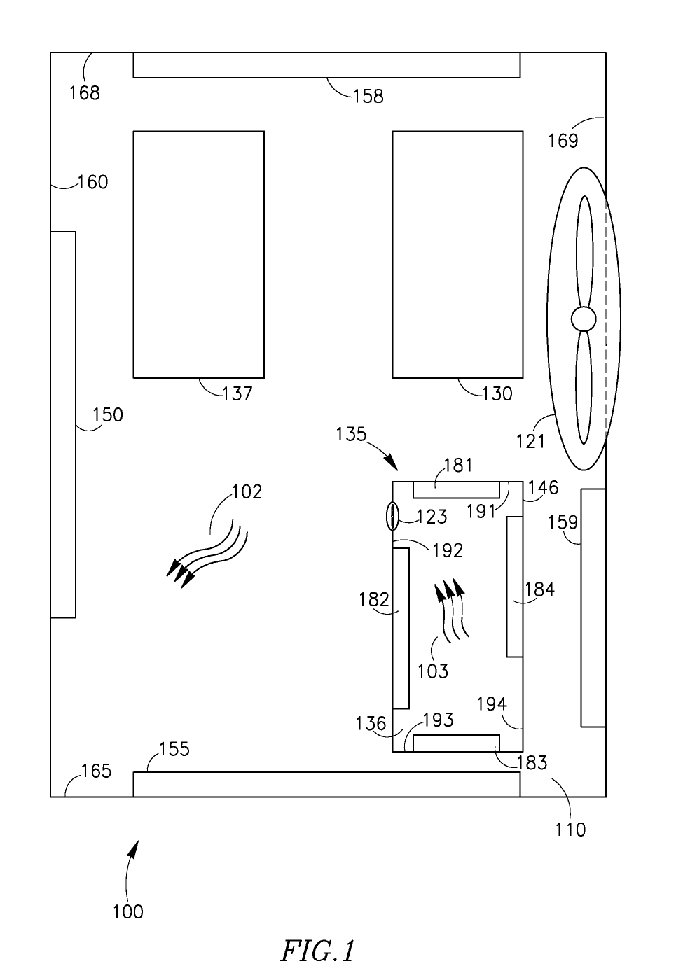

Reference is made to FIG. 1, which schematically illustrates a system 100 of utilizing radiation in an enclosed space 110, in accordance with some demonstrative embodiments.

In some embodiments, system 100 may utilize energetic radiation 102, e.g., infrared radiation, or other spectra of electromagnetic radiation, emitted within enclosed space 110, which may contain one or more machines. Enclosed space 110 may contain, for example, a machine 130, a machine 137, and/or a machine 135, which may emit radiation 102 during operation.

System 100 may include one or more photovoltaic panels 150, 155, 158 and/or 159, to convert radiation 102 into electric voltage, which is used to power or contribute to a power supply of an electrical device 121, which may perform an operation associated with enclosed space 110. For example, and not limited in this respect, electrical device 121 may include a heat dissipation device, e.g., a ventilation fan, an air conditioner, an exhaust vent or the like, to cool enclosed space 110, e.g., during operation of machines 130, 135 and/or 137, as described in detail below. Photovoltaic panels 150, 155, 158 and/or 159 may include a plurality of interconnected photovoltaic cells, as are known in the art, and may be capable of converting radiation 102 into electric voltage to be supplied to electrical device 121, or to a power supply of electrical device 121.

Photovoltaic panels 150, 155, 158 and/or 159 may be installed at suitable locations within enclosed space 110, for example, attached to an inner surface of one or more walls, a ceiling and/or a floor of enclosed space 110, and/or in the vicinity of one or more of machines 130, 135 and 137, and/or at other suitable locations within enclosed space 110, so as to absorb a considerable portion of radiation 102. As a demonstrative non-limiting example, photovoltaic panel 150 may be installed on a wall 160 of enclosed space 110; photovoltaic panel 159 may be installed on a wall 169 of enclosed space 110; photovoltaic panel 155 may be installed on a floor 165 of enclosed space 110; and photovoltaic panel 158 may be installed on a ceiling 168 of enclosed space 110.

Electrical device 121 may be installed at a suitable location within enclosed space 110, to perform a desired operation associated with enclosed space 110. For example, and not limited in this respect, electrical device 121 may include a ventilation fan embedded in one of the walls of enclosed space 110, e.g., in wall 169 as shown in FIG. 1, to expel warm air from enclosed space 110 onto the external environment surrounding enclosed space 110. As an additional example, electrical device 121 may include an air conditioning unit, which may be installed on one of the walls or ceiling of enclosed space 110, to cool air inside enclosed space 110.

In some embodiments, system 100 may additionally or alternatively utilize energetic radiation 103 emitted within an enclosed space 136, which may include, for example, an interior space within a housing 146 of machine 135. Machine 135 may include, for example, an electrical or electronic device, e.g., a computing device, which may include one or more internal components, mechanisms, elements and/or circuits that emit radiation 103 during operation of machine 135.

System 100 may include one or more photovoltaic panels 181, 182, 183 and/or 184, to convert radiation 103 into electric voltage, to power or to contribute to powering an electrical component 123, which may perform an operation associated with enclosed space 136, for example, an operation associated with machine 135. For example, and not limited in this respect, machine 135 may include a computing device, and electrical component 123 may include a heat dissipation component, e.g., a ventilation or exhaust fan, to circulate air within and/or out of enclosed space 136. Photovoltaic panels 181, 182, 183 and/or 184 may include a plurality of interconnected photovoltaic cells, as are known in the art, capable of converting radiation 103 into electric voltage to be supplied to electrical component 123.

Photovoltaic panels 181, 182, 183 and/or 184 may be located at suitable locations within enclosed space 136, for example, at one or more inner surfaces of housing 146 of machine 135, in the vicinity of one or more components of machine 135, or at other suitable locations within enclosed space 136, as necessary to efficiently absorb a significant portion of radiation 103. As a demonstrative non-limiting example, photovoltaic panel 181 may be installed on an inner surface 191 of housing 146, photovoltaic panel 182 may be installed on an inner surface 192 of housing 146, photovoltaic panel 183 may be installed on an inner surface 193 of housing 146, and photovoltaic panel 184 may installed on an inner surface 194 of housing 146. This may allow absorption of a considerable portion of radiation 103, as it spreads throughout enclosed space 136.

Electrical component 123 may be installed at a suitable location within enclosed space 136. For example, electrical component 123 may include a ventilation or exhaust fan installed in one of the walls of enclosed space 136, to circulate warm air produced by a processor and/or other components of machine 135 away from these components or other sensitive components of machine 135, e.g., by expelling the warm air out of housing 146.

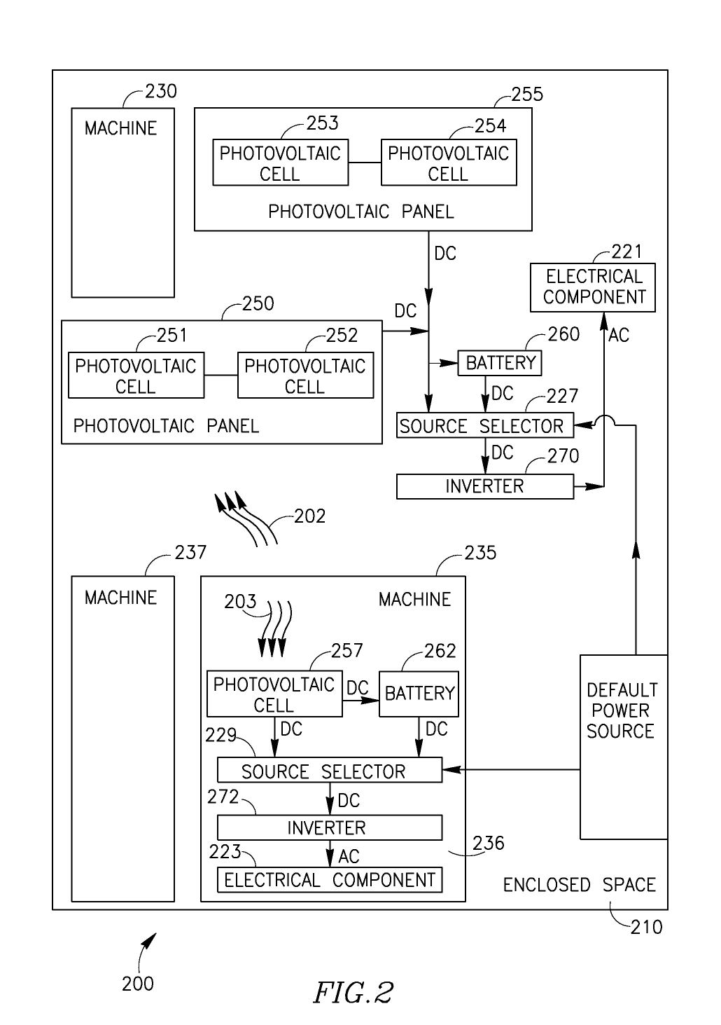

Reference is made to FIG. 2, which schematically illustrates a block diagram of a system 200 utilizing radiation in an enclosed space 210, in accordance with some demonstrative embodiments. In some embodiments, system 200 may perform substantially the same functionalities as system 100 (FIG. 1); for example, one or more elements of system 200 may perform the functionalities of one or more respective elements of system 100, and/or one or more operations of system 200 may be implemented, for example, by one or more elements of system 100, and/or by other suitable units, devices and/or systems.

In some embodiments, system 200 may include one or more photovoltaic panels, for example, a photovoltaic panel 250 and a photovoltaic panel 255, installed at desired positions within enclosed space 210, to convert energetic radiation 202 within enclosed space 210, e.g., infrared radiation, or other spectra of electromagnetic radiation, into an electric voltage, which may be used to power an electrical component 221 associated with enclosed space 210. In some embodiments, enclosed space 210 may contain one or more machines, for example, a machine 235, a machine 230, and/or a machine 237, which may include one or more electric or electronic devices, for example, computing devices. Machines 230, 235, and/or 237 and/or respective components thereof may operate for long periods of time, thereby emitting significant amounts of heat and/or energetic radiation, e.g., infrared radiation.

System 200 may additionally include a photovoltaic panel 257 installed within an interior enclosed space 236 of machine 235, to convert energetic radiation 203 within enclosed space 236 into electric voltage, which may be used to power an electrical component 223 associated with enclosed space 236, e.g., as described above, with reference to enclosed space 136 of machine 135 (FIG. 1).

In some embodiments, system 200 may include one or more electrical devices or components, for example, an electrical device 221 and an electrical component 223, performing one or more operations associated with enclosed space 210 and enclosed space 236, respectively.

As a demonstrative example, and not limited in this respect, electrical device 221 and/or electrical component 223 may include a heat dissipation device or component, for example, a ventilation or exhaust fan, an air conditioner, a water-cooling system, to cool, ventilate and/or expel heat from enclosed space 210 and/or enclosed space 236, respectively. Electrical device 221 may perform an operation associated with enclosed space 210. For example, and not limited in this respect, electrical device 221 may include an air conditioner or a ventilation fan to cool enclosed space 210, and thereby to cool machines 230, 235 and 237, as well as other heat generating devices within enclosed space 210.

Electrical component 223 may be installed inside machine 235, i.e., embedded in or attached to one or more walls of a housing 246 of machine 235. Electrical component 223 may include, for example, a heat dissipation component, e.g., a ventilation fan or exhaust fan, to cool one or more components of machine 235, or to expel warm air from enclosed space 236.

Each of photovoltaic panels 250, 255 may include one or more photovoltaic cells to convert at least a portion of radiation 202 into electric voltage, which may be used to power electrical device 221. Similarly, photovoltaic panel 257 may include one or more photovoltaic cells to convert at least a portion of radiation 203 into electric voltage, which may be used to power electrical component 223. Photovoltaic panels 250, 255, and/or 257 may include thin-film cells, panel cells, or other suitable forms and types of photovoltaic cells as are known in the art; in particular, photovoltaic cells responsive to infrared radiation. For example, in some embodiments, photovoltaic panel 250 may include a photovoltaic cell 251, a photovoltaic cell 252, and/or additional photovoltaic cells, interconnected in an array to form a single installable unit. Similarly, in some embodiments, photovoltaic panel 255 may include a photovoltaic cell 253, a photovoltaic cell 254, and/or additional photovoltaic cells, interconnected in an array to form a single installable unit.

In some embodiments, photovoltaic panel 250 and/or photovoltaic panel 255 may be installed at suitable locations within enclosed space 210. Photovoltaic panel 257 may be installed within enclosed space 236, for example, as an integral element of machine 235, e.g., as described above with reference to panel 157 of system 100 (FIG. 1).

Photovoltaic panels 255 and 250 may be connected to electrical device 221, via an appropriate circuit, to provide the electric power generated by panels 255 and 250 in a form suitable for powering electrical device 221. Similarly, photovoltaic panel 257 may be connected to electrical component 223 via an appropriate circuit to provide the electric power generated by panel 257 in a form suitable for powering electrical component 223.

In some embodiments, for example, photovoltaic panels 255 and 250 may be connected to electrical component 221 via an inverter 270, to invert direct current (DC) generated by photovoltaic panels 255 and/or 250 into alternating current (AC), which may be required for powering electrical component 221.

Additionally or alternatively, in some embodiments, photovoltaic panels 255 and 250 are connected to a battery 260, which may configured to be charged, by the power photovoltaic panels 250 and 255, and thereby to retain electric energy produced by the photovoltaic panels. Battery 260 may provide the retained electric energy to power electrical component 221, directly or via inverter 270. In some embodiments, electrical component 221 may be connected to an additional power source, e.g., to an electric grid, in order to ensure a continuous supply of electric power to device 221, regardless of the relative power contributions of photovoltaic panels 250 and 255, and/or of battery 260.

Photovoltaic panel 257 may be connected to electrical component 223 via an inverter 272, within enclosed space 236, to invert DC power generated by photovoltaic panel 257 into AC power, which may be required for powering electrical component 223.

Additionally or alternatively, in some embodiments, photovoltaic panel 257 may be connected to a battery 262, within enclosed space 236, to retain electric energy generated by photovoltaic panel 257. In some embodiments, for example, if machine 235 includes a battery-powered device, e.g. a mobile computer or the like, photovoltaic panel 257 may be connected to a main battery of machine 235. Alternatively, panel 257, inverter 272 and battery 262 may operate as a separate circuit to power electrical component 223 directly. In some embodiments, electrical component 223 may be connected to an additional power supply, e.g., to a main power supply of machine 235, thereby to ensure continuous supply of electric power to component 223, regardless of the relative power contributions of photovoltaic panel 257 and/or battery 262.

In some embodiments, electrical device and/or electrical component 223 may be connected to the various power sources described above via a source selector 227 and/or a source selector 229, respectively, which may periodically select among the various sources providing electric power to components 221 and 223, respectively, as is known in the art.

As a demonstrative, non-limiting example, source selector 227 may prioritize the power sources of device 221 such that a highest priority is given to supplying power directly from photovoltaic panels 255 and 250, then from battery 260, and finally from a default power source, e.g., an electric grid. This may ensure receiving sufficient electricity for the operation of electrical component 221, while utilizing as much as possible of the power generated by photovoltaic panels 250 and 255. Similarly, source selector 229 may prioritize the power sources of component 223 such that a highest priority is given to supplying power directly from photovoltaic panel 257, then from battery 262, and finally from a default power source, e.g., a main battery or main power supply of machine 235.

Other suitable operations or sets of operations may be used in accordance with embodiments of the invention.

Functions, operations, components and/or features described herein with reference to one or more embodiments, may be combined with, or may be utilized in combination with, one or more other functions, operations, components and/or features described herein with reference to one or more other embodiments, or vice versa.

While certain features of the invention have been illustrated and described herein, many modifications, substitutions, changes, and equivalents may occur to those skilled in the art. It is, therefore, to be understood that the appended claims are intended to cover all such modifications and changes as fall within the true spirit of the invention.

What is claimed is:

1. A system of utilizing energetic radiation in an enclosed space, the system comprising:
one or more photovoltaic cells, positioned at one or more predetermined positions in said enclosed space, adapted to convert radiation in said enclosed space into electric power; and
an electric circuit to utilize said electric power to perform a function associated with said enclosed space.

2. The system of claim 1, wherein said electric circuit comprises an electric component that is physically associated with said enclosed space that performs said function, and that is physically associated with said enclosed space.

3. The system of claims 2 wherein said electric component comprises a heat dissipation device to cool at least a portion of said enclosed space.

4. The system of claim 3, wherein said heat dissipation device comprises a fan to circulate air in said enclosed space.

5. The system of claim 1, wherein said electric circuit comprises a battery configured to be charged by at least part of said electric power.

6. The system of claim 2, wherein said enclosed space comprises a space enclosed within a housing of a machine.

7. The system of claim 6, wherein said machine comprises an electronic device.

8. The system of claim 7, wherein said electric power is coupled to a power supply of said electronic device.

9. The system of claim 8, wherein said electronic device comprises a computing device.

10. The system of claim 1, wherein said enclosed space contains one or more machines that emit at least part of said energetic radiation.

11. The system of claim 10 wherein said enclosed space comprises a room and wherein at least one of said machines comprises a computer.
